(19) United States
(12) Patent Application Publication
(10) Pub. No.: US 2002/0076934 A1
(43) Pub. Date: Jun. 20, 2002

(54) Method of removaling photoresistance

(76) Inventors: Chun-Chieh Fang, TaiNan (TW); Po-Sheng Hu, Taipei (TW); Yu-Chun Ho, Taipei (TW)

Correspondence Address: BACON & THOMAS, 4th Floor, 625 Slaters Lane, Alexandria, VA, 22314, US

(21) Appl. No.: 09/736,288

(22) Filed: Dec. 15, 2000

(51) Int. Cl. H01L 21/3205; H01L 21/4763; H01L 21/311

(52) U.S. Cl. 438/694

(57) ABSTRACT

A method of removaling photoresistance is disclosed: first, unqualified pattern on the substrate is taken away by a plasma process under a mixture of oxygen and fluorocarbon gases. Thereafter, the polymer, which is produced by reaction between the plasma and photoresist, is removed by organic solvent (ACT690/NMP). When the plasma process is applied, the plasma process also could over-etch in the silicon-oxy-nitride layer and the polymer is entirely taken off in the plasma process. Silicon-oxy-nitride is then deposited to complement the loss part in the plasma process. After that, lithography process repeats again to form a new pattern. Finally, ADI is performed to make sure if the new pattern is in the acceptable range of the process. Next, metal layer and silicon-oxy-nitride layer are patterned by the new pattern to form the interconnect. Finally, pattern is removed by the plasma under oxygen gas and the interconnect is then finished

### BACKGROUND OF THE INVENTION

1. Field of the Invention

The present invention relates to a method of processing semiconductor chips, and peculiarly to a process for re-patterning metal lines with the advantage of removing the stubborn residue on an antireflection layer (ARC).

2. Description of the Related Art

The era of silicon Ultra-Large-Scale-Integration (ULSI) has spurred an increasing level of function integration on-chip, driving a need for greater circuit density and higher performance. That's why multilevel interconnects are applied in ULSI field. Decreasing the width of interconnects is also a way to improve the function integration on-chip.

Photolithography has been used during the manufacture of the interconnect. An anti-reflection layer (ARC) is deposited over the metal layer to prevent the reflection from the metal layer in the lithography process. The anti-reflection layer (ARC layer) is often made of titanium (Ti), titanium nitride (TiN) or titanium tungsten (TiW) when the metal layer is composed of aluminium (Al). Continually advancing technical innovation in lithography has brought about use of shorter wavelength to get 0.25 um or less in width (e.g., use of a KrF excimer laser light source). There are a lot of problems to be solved before such shorter wavelength is realized. One of the problems is that ARC layer could not work well in the lithography process with shorter wavelength. The reflection, which comes from prior ARC layer, becomes larger in the photolithography process. Particularly, when titanium (Ti), titanium nitride (TiN) or titanium tungsten (TiW) is applied to form the ARC layer, there is more than 50% reflection in the lithography process. To solve this problem, dielectric material is selected to become ARC layer. Dielectric materials have several characters such as lower reflection constant (n) and dielectric constant (k). A dielectric material such as Silicon-Oxy-Nitride (SiOₓN_{y}) is most wildly used as being ARC layer in the interconnet process. Silicon-Oxy-Nitride (SiOₓN_{y}) is formed by chemical vapor deposition (CVD) process, moreover SiOₓN_{y} could modify its the ratio of reaction gases in CVD process to obtain the different reflection constants (n) and dielectric constants (k).

Referring now to FIGS. 1A, there is shown a schematic process cross-sectional view of a silicon substrate 10 where the device is built. A metal layer 15 and a SiOₓN_{y} layer 21 are sequentially formed on the surface of the substrate 10 as shown in FIG. 1A. The SiOₓN_{y} layer 21 is used to an ARC layer in a lithography process to prevent reflection. First, photoresist is coated on the substrate 10. Soft bake and hard bake are performed to solidify photoresist. After photoresist is solidified, an exposure process could be applied in the next step.

The priming process could be used before photoresist is coated on the substrate 10 to improve the adhesion between the SiOₓN_{y} layer 21 and photoresist. Users often use HMDS 30 (hexamethyldisilane) in the priming process. Thereafter, the exposed photoresist is performed a development process to form pattern 40. In the prior process, a developing process is using dip technique. Finally, the metal layer 15 is etched according to pattern 40 to form interconnect.

Before etching the metal layer 15, ADI (After develop inspection) is performed to make sure if size and shape of the pattern 40 are in the acceptable range of the process. If the result of ADI is bad, pattern 40, which is composed with photoresist, will be entirely removed. The process of coating, exposure and development will repeat again to form a new pattern.

Two-step of cleaning photoresist is performed. In first step, acetone or O₂ plasma is chosen to remove bad pattern 40 roughly. Organic solvent, which contains ACT690/NMP is performed to remove photoresist in the second step. But two-step cleaning could not eliminate photoresist entirely. Residue 100 is found the interface between the SiOₓN_{y} layer 20 and the HMDS 30 as shown in FIG. 1B. Existence of the residue 100 leads failure of creating a new pattern 40. It is the problem in the exposure process that the surface of the substrate is not smooth because of the existence of the residue 100.

In accordance with the present invention, the stubborn residue 100 could be removed and the surface of the substrate is enough flatness to create a new pattern. The substrate could be reuse again to lower the cost.

### SUMMARY OF THE INVENTION

Accordingly, it is a primary object of the present invention to provide a method of removing photoresist by treating plasma under a mixture of oxygen and fluorocarbon gases. The plasma under a mixture of oxygen and fluorocarbon gases could clean the rigid residue and therefore the new pattern could be rebuilt successfully.

It is another object of the present invention to provide a method of removing photoresist with an advantage of partially or totally eliminating the silicon-oxy-nitride layer in the same procedure. The yield will be improved by consequentially deposition fresh silicon-oxy-nitride without the rigid residue.

In accordance with the objects of this invention, there is shown a method of removing photoresist. First, unqualified pattern on the substrate is taken away by a plasma process under a mixture of oxygen and fluorocarbon gases. Thereafter, the polymer, which is which is produced by reaction between the plasma and photoresist, is removed by organic solvent (ACT690/NMP). When the plasma process is applied, the plasma process also could over-etch in the silicon-oxy-nitride layer and the polymer is entirely taken off in the plasma process. silicon-oxy-nitride is then deposited to complement the loss part in the plasma process. After that, lithography process repeats again to form a new pattern. Finally, ADI is performed to make sure if the new pattern is in the acceptable range of the process. Next, metal layer and silicon-oxy-nitride layer are patterned by the new pattern to form the interconnect. Finally, pattern is removed by the plasma under oxygen gas and the interconnect is then finished.

### BRIEF DESCRIPTION OF THE DRAWINGS

The accompanying drawings forming a material part of this description, in which:

FIGS. 1A to 1B are cross sectional representations of forming pattern and taking off unqualified pattern according to the prior arts.

FIGS. 2A to 2D are cross sectional representations of taking off unqualified pattern and re-forming a silicon-oxy-nitride layer according to the embodiment of the present invention.

### DESCRIPTION OF THE PREFERRED EMBODIMENTS

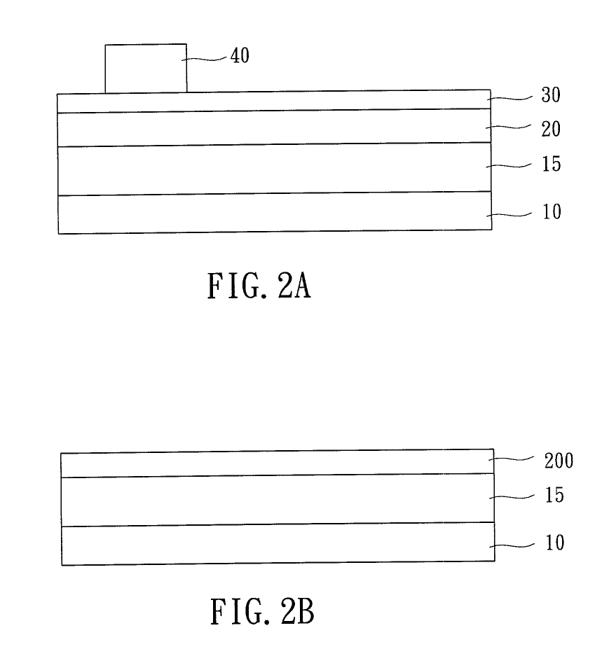

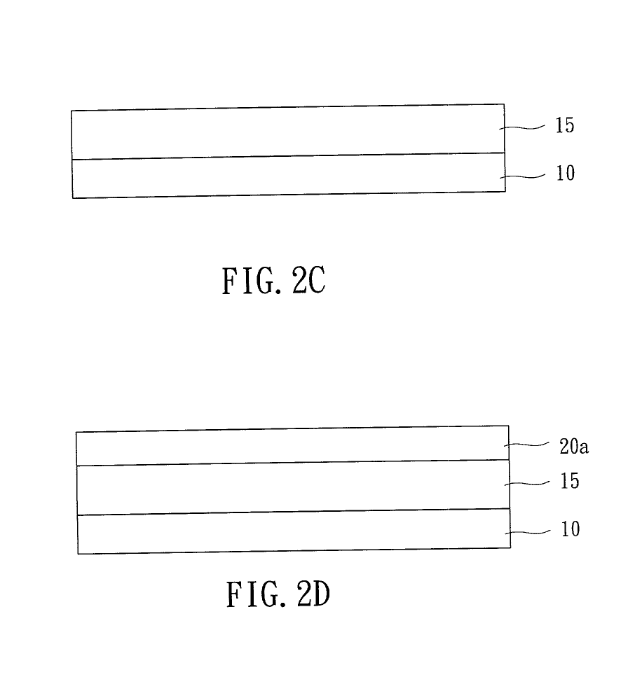

The invention disclosed herein is directed to a method of forming the pattern of the metal lines. The plasma with oxygen and fluorocarbon gases replaces the plasma with oxygen in the removing unqualified pattern process. FIGS. 2A-2D show sectional representations of taking off unsuited pattern and re-forming a silicon-oxy-nitride layer according to the embodiment of the present invention, respectively.

First, referring now to FIG. 2A, a silicon substrate 10 where the device is built is provided by this present invention. Next, a metal layer 15 and a SiOₓN_{y} layer 20 are sequentially formed on the substrate 10 as shown in FIG. 2A. The SiOₓN_{y} layer 20 is used to an ARC layer, which could prevent reflection to improve the accuracy of exposure in a lithography process. After that, coating and solidifying processes are performed to form photoresist on the substrate 10. Alternatively, the solidifying process contains two steps: soft bake and hard bake. After conventional exposing and developing the photoresist, a pattern 40 is then finished.

The metal layer 15 is usually aluminum alloy such as aluminum (Al), aluminum copper (AlCu) or aluminum silicon copper (AlSiCu). Alternatively, the metal layer 15 is using copper for the concern of decreasing metal reisit. The SiOₓN_{y} layer 20 is usually using chemical vapor deposition (CVD) technique.

Alternatively, the photoresist is usually orgainc material but the adhesion between metal layer 15 and photoresist is bad. To improve the adhesion, a priming process could be used before photoresist is coated on the substrate 10. HMDS 30 (hexamethyldisilane) is usually using in the priming process. Therefore, HMDS 30 is coated on the SiOxNy layer 20 before the photoresist is formed on the substrate. Thereafter, the HMDS 30's surface energy is equal to the photoresist's and the substrate 10 could adhere to photoresist well by the HMDS 30.

Still referring now to FIG. 2A, ADI (After develop inspection) process is performed to check the pattern 40, before the metal layer 15 is etched in according to the profile of the pattern 40. If the result of ADI is bad, pattern 40, which is composed with photoresist, will be entirely removed. The process of coating, exposure and development will repeat again to form a new pattern.

The bad pattern 40 is removed by plasma and organic solvent. The key point of the present invention is using the plasma under a mixture of tetrafluoromethane and oxygen gases, to take off the photoresist on the substrate 10. Next, organic solvent such as ACT690/NMP is performed to remove polymer, which is produced by reaction between the plasma and photoresist.

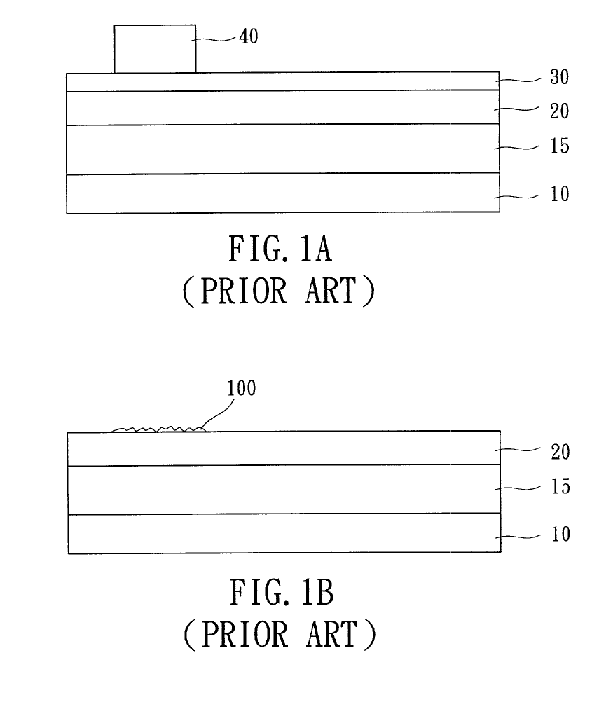

The operation temperature of plasma is between 100° C. and 150° C. and relative volume gas ratio(tetra-fluoromethane : oxygen) is 1:20 to 1:10. The residue 100 in the prior art (as shown in FIG. 1B) could be removed entirely after plasma treatment in the present invention. The reason is that the residue 100, which is Si—O bond-bearing polymer, is produced from HMDS or SiOₓN_{y} in the plasma process. In the prior, the plasma under the oxygen gas could not take off residue well.

Alternatively, the plasma operation time depends on the process demand. Referring now to FIG. 2B, the photoresist and top layer of SiOₓN_{y} layer 20 are etched by extending the operation time. Thereafter, SiOₓN_{y} 200 on the metal layer 15 has no more residues. Next, SiOₓN_{y} 20a is formed on the SiOₓN_{y} 200 to complement the loss of SiOₓN_{y} in the plasma treatment.

Referring now FIG. 2C, the SiOₓN_{y} 200 layer could also be removed totally by extend the plasma operation time and the residues are no longer shown on the substrate 10. Next, SiOₓN_{y} is performed to form SiOₓN_{y} layer 20a by CVD technique as shown in FIG. 2D. Alternatively, the SiOₓN_{y} layer 20a's thickness is same as the SiOₓN_{y} layer 20's.

Thereafter, photoresist is coated on the SiOₓN_{y} layer 20 again and then photoresist is sequentially performed the exposure and development process to form the new pattern. Next, the new pattern is still proceeded by ADI step. If size and shape of the new pattern are in the acceptable range of the process, the substrate 10 could be proceeded to the next step. If not, the new pattern should be removed again.

Thereafter, metal layer and SiOₓN_{y} layer are then patterned to define interconnect according to the profile of the pattern. Alternatively, anisotropic etching is performed to pattern the matel layer and the SiOₓN_{y} layer. Finally, pattern 40 is typically removed by plasma under oxygen gas and the interconnect is then finished.

As mentioned above, the present invention provides a process to take off bad pattern by using plasma under a mixture of tetra-fluoromethane and oxygen gases. Compared to the prior arts using plasma only under oxygen gas, the present invention could provide extremely planar surface for lithography. Therefore, the present invention could lower the cost. While the invention has been particularly shown and described with reference to the preferred embodiments, it will be understood by those skilled in the art that various changes in form and detail may be made therein without departing from the spirit and scope of the present invention.

What we claimed is:

1. A method of removing photoresist, comprising the steps of:
(a) providing a plasma under a mixture of tetra-fluoromethane and oxygen gases to take off most part of photoresist and a silicon-oxy-nitride (SiONy) layer on a substrate, wherein said substrate is sequentially formed hexamethyldisilane (HMDS) layer, said SiOₓN_{y} layer, and said photoresist;
(b) taking off polymer and the other part of said photoresist by ACT690/NMP solvent, wherein said polymer is produced by reaction between said plasma and said photoresist;
(c) forming a SiOₓN_{y} layer on said substrate.

2. The method of removing photoresist as set forth in claim 1, wherein said tetra-fluoromethane and said oxygen gases are provided at relative volume ratio of from 1:20 to 1:10.

3. The method of removing photoresist as set forth in claim 1, wherein said plasma reacts between 100° C. and 150° C.

4. The method of removing photoresist as set forth in claim 1, wherein said SiOₓN_{y} layer is formed by chemical vapor deposition (CVD).

5. The method of removing photoresist as set forth in claim 1, wherein said SiOₓN_{y} layer in the step (a) is partially etched by said plasma.

6. The method of removing photoresist as set forth in claim 1, wherein said SiOₓN_{y} layer in the step (a) is totally etched by said plasma.

7. The method for removing photoresist on an anti reflection (ARC) layer comprising plasma etching to remove most part of said photoresist on said anti reflection layer and ACT690/NMP solvent to remove the polymer and the other part of photoresist, chrachterized in that said plasma under a mixture of tetra-fluoromethane and said oxygen gases to take off the said photoresist and said polymer which is on the interface of said anti reflection layer.

8. The method for removing photoresist on an anti reflection layer as set forth in claim 7, wherein said anti reflection layer is composed by a silicon-oxy-nitride (SiOₓN_{y}) layer.

9. The method for removing photoresist on an anti reflection layer set forth in claim 7, wherein said anti reflection layer is partially etched by said plasma etching.

10. The method for removing photoresist on an anti reflection layer set forth in claim 7, wherein said SiOₓN_{y} layer is totally etched by said plasma etching.

11. The method for removing photoresist on an anti reflection layer set forth in claim 7, wherein said tetra-fluoromethane and said oxygen gases are provided at relative volume ratio of from 1:20 to 1:10.

12. The method for removing photoresist on an anti reflection layer set forth in claim 7, wherein said plasma etching reacts between 100° C. and 150° C.

13. A method of reforming metal line's pattern, comprising the steps of:
(a) providing a substrate with unqualified metal line's pattern, wherein the said substrate sequentially formed hexamethyldisilane (HMDS) layer, silicon-oxy-nitride (SiOₓN_{y}) layer, and metal layer;
(b) providing a plasma under a mixture of tetra-fluoromethane and oxygen gases to take off most part of said pattern and said SiOₓN_{y} layer on a substrate;
(c) taking off polymer and the other part of said pattern by ACT690/NMP solvent, wherein said polymer is produced by reaction between said plasma and said photoresist;
(d) forming a SiOₓN_{y} layer on said substrate;
(e) sequentially coating, exposing and developing photoresist to create a new metal line's pattern.

14. The method of reforming metal line's pattern as set forth in claim 13, wherein said tetra-fluoromethane and said oxygen gases are provided at relative volume ratio of from 1:20 to 1:10.

15. The method of reforming metal line's pattern as set forth in claim 13, wherein said plasma in step (b) reacts between 100° C. and 150° C.

16. The method of reforming metal line's pattern as set forth in claim 13, wherein said SiOₓN_{y} layer in step (d) is formed by chemical vapor deposition (CVD).

17. The method of reforming metal line's pattern as set forth in claim 13, wherein said SiOₓN_{y} layer in the step (b) is partially etched by said plasma.

18. The method of reforming metal line's pattern as set forth in claim 13, wherein said SiOₓN_{y} layer in the step (b) is totally etched by said plasma.
